(19) United States
(12) Patent Application Publication
(10) Pub. No.: US 2014/0291290 A1
(43) Pub. Date: Oct. 2, 2014

(54) PLASMA PROCESSING APPARATUS AND METHOD THEREOF

(71) Applicant: Panasonic Corporation, Osaka (JP)

(72) Inventors: Taro KITAOKA, Kyoto (JP); Tomohiro OKUMURA, Osaka (JP)

(73) Assignee: PANASONIC CORPORATION, Osaka (JP)

(21) Appl. No.: 14/220,133

(22) Filed: Mar. 20, 2014

(30) Foreign Application Priority Data
Mar. 28, 2013 (JP) 2013-068111
Dec. 25, 2013 (JP) 2013-266807

(51) Int. Cl. H01J 37/32

(52) U.S. Cl. CPC H01J 37/32009
USPC 216/68; 118/723 R; 427/569; 156/345.29

(57) ABSTRACT

In an inductive coupling type plasma torch unit, a solenoid coil is arranged in the vicinity of a first quartz block and a second quartz block, and a space inside a long chamber is annular. Plasma generated in the space inside the long chamber is jetted toward a base material from a plasma jetting port) as a slit-shaped opening in the long chamber. The base material is processed by relatively moving the long chamber and a base material holding mechanism holding the base material inside the annular chamber in a direction perpendicular to the longitudinal direction of the plasma jetting port.

### BACKGROUND OF THE INVENTION

1. Field of the Invention

The present invention relates to a plasma processing apparatus and a method thereof.

2. Description of Related Art

A thin film of a semiconductor such as polycrystalline silicon (poly-Si) has been widely used for a thin-film transistor (TFT) or a solar cell from the past. In particular, a poly-Si TFT has characteristics in which the carrier mobility is high and it can be formed on a transparent insulating substrate such as a glass substrate. The poly-Si TFT is widely used by exploiting these characteristics, for example, for a switching device included in a pixel circuit of a liquid crystal display, a liquid crystal projector, an organic EL device and so on, or a circuit device of a driver for driving liquid crystal.

As a method of fabricating a high-performance TFT on the glass substrate, there exists a manufacturing method generally called a “high-temperature process”. A process using high temperature which is approximately 1000° C. at the maximum during the process is generally called the “high-temperature process” in manufacturing processes of the TFT. The high-temperature process is characterized in a point that polycrystalline silicon having relatively high quality can be deposited by solid phase epitaxy of silicon, a point that a gate insulating layer having high quality can be obtained by thermal oxidation of silicon and a point that a clean interface between the polycrystalline silicon and the gate insulating layer can be formed. In the high-temperature process, the high-performance TFT having high mobility and high reliability can be stably manufactured based on these characteristics.

As the high-temperature process is a process of crystallizing the silicon film by the solid phase epitaxy, heat treatment is necessary at a temperature approximately 600° C. for a long time such as approximately 48 hours. As this is the process performed for a very long period of time, there are problems that many furnaces for heat treatment are inevitably necessary for increasing throughput of the process and thus it is difficult to reduce costs. Additionally, the costs for substrates are high as it is inevitable to use quartz glass as an insulating substrate having high heat resistance, therefore, the process is regarded not suitable for increase the area.

On the other hand, a technique for reducing the maximum temperature in the process and manufacturing the poly-Si TFT on an inexpensive glass substrate having the large area is a technique called a “low-temperature process”. In the manufacturing process of the TFT, a process of manufacturing the poly-Si TFT on the relatively inexpensive glass substrate having heat resistance in temperature environment in which the maximum temperature is approximately 600° C. or less is generally called the “low-temperature process”. In the low-temperature process, a laser crystallization technique performing crystallization of the silicon film by using pulse laser in which oscillation time is extremely short is widely used. The laser crystallization is a technique in which the silicon thin-film on the substrate is irradiated with high-output pulse laser light to be instantly fused and a property that the fused silicon is crystallized in a process of being solidified is used.

However, the above crystallization technique has some large problems. As one of them, there is a problem of many trap levels locally existing inside a polysilicon film formed by the laser crystallization technique. The existence of the trap levels causes adverse effects such as the reduction of mobility in the TFT and the increase of a threshold voltage because carriers which are supposed to be moved in an active layer by voltage application are trapped and do not contribute to the conduction of electricity. Moreover, there is also a problem that the size of the glass substrate is limited due to the restriction in laser output. In order to improve the throughput in the process of laser crystallization, it is necessary to increase the area which can be crystallized by one irradiation. However, there is a restriction in laser output at present, therefore, a long period of time is required for crystallizing a piece of substrate when the above crystallization technique is applied to a large-sized substrate such as a seventh generation (1800 mm×2100 mm) substrate.

Furthermore, in the laser crystallization technique, scanning is generally performed with line-shaped laser, thereby performing crystallization. The line beam is shorter than the width of the substrate as there is the restriction in laser output, therefore, it is necessary to perform scanning with the laser several times for crystallizing the entire substrate surface. Accordingly, seam regions of line beams may be generated in the substrate, and a region to be scanned twice will exist. The crystallinity in this region largely differs from the crystallinity in a region crystallized by being scanned once. Accordingly, device characteristics of these regions largely differ, which will be a large factor of device variations. Lastly, as a laser crystallization device has a complicated device structure and costs of consumable components are high, there is a problem that device costs and running costs are high. As a result, manufacturing costs of the TFT using the polysilicon film crystallized by the laser crystallization device will be high.

In order to solve the problems such that there is a restriction in substrate size and that devices costs are high, a crystallization technique called a “thermal plasma jet crystallization method” has been studied (for example, refer to S. Higashi, H. Kaku, T. Okada, H. Murakami and S. Miyazaki, Jpn. J. Appl. Phys. 45, 5B (2006) pp. 4313-4320 (Non-Patent Document 1), the contents of which are incorporated herein by reference). The present technique will be briefly explained. When a cathode of tungsten (W) is allowed to face an anode of water-cooled copper (Cu) and a DC voltage is applied, arc discharge occurs between both electrodes. When argon gas is allowed to flow between these electrodes under atmospheric pressure, thermal plasma is jetted from a jetting hole formed in the copper anode. The thermal plasma is thermal equilibrium plasma, which is an ultra-high temperature heat source in which temperatures of ion, electrons, neutral atoms and so on are approximately equivalent, namely, approximately 10000K. Accordingly, the thermal plasma can easily heat an object to be heated to a high temperature, therefore, an a-Si film can be crystallized when a substrate on which the a-Si film is deposited scans the front of the ultra-high temperature thermal plasma at high speed.

As the device structure is extremely simple as described above and the crystallization process is performed under atmospheric pressure, it is not necessary to cover the device by an expensive member such as an airtight chamber, and it is expected that device costs will be extremely low. As utilities necessary for the crystallization are argon gas, electric power and cooling water, running costs of the crystallization technique are also low.

FIG. 12 is a schematic view for explaining a crystallization method of a semiconductor film using the thermal plasma.

In the drawings, a thermal plasma generating apparatus 31 includes a cathode 32 and an anode 33 arranged so as to face the cathode 32 with a given distance apart from the cathode 32. The anode 32 is made of an electric conductor such as tungsten. The anode 33 is made of an electric conductor such as copper. The anode 33 is formed in a hollow shape, which can be cooled by allowing water to pass through the hollow portion. The anode 33 is also provided with a jetting hole (nozzle) 34. When direct current (DC) voltage is applied between the cathode 32 and the anode 33, arc discharge occurs between both electrodes. In this state, a gas such as argon gas is allowed to flow between the cathode 32 and the anode 33 under atmospheric pressure, thereby jetting a thermal plasma 35 from the jetting hole 34. Here, the “thermal plasma” is thermal equilibrium plasma, which is the ultra-high temperature heat source in which temperatures of ion, electrons, neutral atoms and so on are approximately equivalent, namely, approximately 10000K.

The above thermal plasma can be used for heat treatment for crystallization of the semiconductor film. Specifically, a semiconductor film 37 (for example, an amorphous silicon film) is formed on a substrate 36 and the thermal plasma (thermal plasma jet) 35 is applied to the semiconductor film 37. At this time, the thermal plasma 35 is applied to the semiconductor film 37 while relatively moving along a first axis (a right and left direction in the shown example) parallel to the surface of the semiconductor 37. That is, the thermal plasma 35 is applied to the semiconductor film 37 while being scanned in the direction of the first axis. Here, “to relatively move” means that the semiconductor film 37 (and the substrate 36 supporting the film) and the thermal plasma 35 are relatively moved, including a case of moving only one of them and a case of moving both of them. The semiconductor film 37 is heated by the high temperature included in the thermal plasma 35 by the scanning of the thermal plasma 35, and a crystallized semiconductor film 38 (a polysilicon film in the example) can be obtained (refer to, for example, JP-A-2008-53634 (Patent Document 1), the contents of which are incorporated herein by reference).

FIG. 13 is a conceptual view showing the relation between the depth from the outermost surface and the temperature. As shown in the drawing, only a region near the surface can be processed at the high temperature by moving the thermal plasma 35 at high speed. After the thermal plasma 35 passes by, the heated region is rapidly cooled, therefore, the region near the surface becomes high in temperature for an extremely short period of time.

The above plasma is generally generated at dot-like regions. The thermal plasma is maintained by thermoelectronic emission from the cathode 32, and the thermoelectronic emission becomes more active in a position where the plasma density is higher, therefore, the plasma density becomes higher and higher due to the positive feedback. That is, the arc discharge is intensively generated at one point in the cathode, and thermal plasma is generated at dot-like regions.

In the case where a plate-shaped base material is desired to be uniformly processed as in the crystallization of the semiconductor film, it is necessary to scan dot-like thermal plasma over the entire base material. It is effective to widen an irradiation region of thermal plasma for constructing the process which can be processed in a short period of time by reducing the number of scanning times. Accordingly, a technique of performing scanning only in one direction by generating the long thermal plasma has been studied (for example, refer to WO2011/142125, JP-A-2012-38839, JP-A-2012-54129, JP-A-2012-54130, JP-A-2012-54131, JP-A-2012-54132, JP-A-2012-174499 and JP-A-2012-174500 (Patent Documents 2 to 9), the contents all of which are incorporated herein by reference).

Moreover, it is reported that, when an insulating material is inserted between dot-like thermal plasma to form a chamber to have an annular shape, the thermal plasma becomes annular, and when the annular chamber is formed to have a narrow string shape by using the insulating material so as to partially open the chamber, the base material can be exposed to the long thermal plasma (for example, refer to T. Okumura and H. Kawaura, “Elongated Inductively Coupled Thermal Plasma Torch Operable in Atmospheric Pressure”, Proc. Symp. Dry Process (2012) p. (Non-Patent Document 2), the contents of which are incorporated herein by reference. In this structure, the base material is arranged on the outer periphery of the annular chamber.

### SUMMARY OF THE INVENTION

However, in an application of performing high-temperature processing to the region near the surface of a base material for an extremely short period of time such as in the crystallization of semiconductors, there is a problem that it is difficult to sufficiently heat the temperature of the substrate as a portion where the plasma has the highest temperature is apart from the substrate in the technique of generating the thermal plasma in a long shape shown in related-art examples described in Patent Documents 2 to 9. Also in the in technique shown in the related-art example described in Non-Patent Document 2, the base material is positioned on the outer periphery of the annular chamber, and the annular plasma will be concentrated on the center of the annual chamber, therefore, the plasma is distant from the base material and it may be difficult to obtain sufficient thermal efficiency when the chamber and the base material are apart from each other.

The present invention has been made in view of the above problems, and an object thereof is to provide a plasma processing apparatus and a method thereof capable of generating plasma stably and efficiently as well as processing the entire desired region to be processed on a base material efficiently for a short period of time when performing high-temperature heat processing to the region near the surface uniformly for an extremely short period of time, or when performing low-temperature plasma processing to the base material by irradiating the base material with plasma using reactive gas or with plasma and a reactive gas flow at the same time.

According to an embodiment of the present invention there is provided a plasma processing apparatus including an annular chamber surrounded by a dielectric member, an opening communicating to the annular chamber, a gas supply pipe for introducing gas into the annular chamber, a coil provided in the vicinity of the annular chamber and a high-frequency power supply connected to the coil, in which a base material holding mechanism holding a base material inside the annular chamber and the coil is further included.

In the above structure, it is possible to generate plasma stably and efficiently when performing high-temperature heat treatment to a region near the surface of the base material uniformly for an extremely short period of time, or when performing low-temperature plasma processing to the base material by irradiating the base material with plasma by reactive gas or with plasma and a reactive gas flow at the same time.

According to another embodiment of the invention, there is provided a plasma processing apparatus including an annular chamber surrounded by a dielectric member, an opening communicating to the annular chamber, a gas supply pipe for introducing a gas into the annular chamber, a coil provided in the vicinity of the annular chamber, and a high-frequency power supply connected to the coil, in which a base material holding mechanism holding plural base materials outside the annular chamber is further included.

In the above structure, it is possible to generate plasma stably and efficiently when performing high-temperature heat treatment to the region near the surface of the base material uniformly for an extremely short period of time, or when performing low-temperature plasma processing to the base material by irradiating the base material with plasma by reactive gas or with plasma and the reactive gas flow at the same time.

According to an embodiment of the present invention, there is provided a plasma processing method including the steps of injecting gas from an opening communicating to an annular chamber toward a base material held inside the annular chamber while supplying the gas into the annular chamber surrounded by a dielectric member and supplying high-frequency power to a coil to generate a high-frequency electromagnetic field inside the annular chamber and generate plasma to thereby process the surface of the base material.

In the above structure, it is possible to generate plasma stably and efficiently as well as to process the entire desired region to be processed on the base material efficiently for a short period of time when performing high-temperature heat treatment to the region near the surface of the base material uniformly for an extremely short period of time, or when performing low-temperature plasma processing to the base material by irradiating the base material with plasma by reactive gas or with plasma and the reactive gas flow at the same time.

According to another embodiment of the present invention, there is provided a plasma processing method including the steps of injecting gas from an opening communicating to an annular chamber toward plural base materials held outside the annular chamber while supplying the gas into the annular chamber surrounded by a dielectric member and supplying high-frequency power to a coil to generate a high-frequency electromagnetic field inside the annular chamber and generate plasma to thereby process the surface of the base material.

In the above structure, it is possible to generate plasma stably and efficiently as well as to process the entire desired region to be processed on the base material efficiently for a short period of time when performing high-temperature heat treatment to the region near the surface of the base material uniformly for an extremely short period of time, or when performing low-temperature plasma processing to the base material by irradiating the base material with plasma by reactive gas or with plasma and the reactive gas flow at the same time.

According to the embodiments of the present invention, it is possible to generate plasma stably and efficiently as well as to process the entire desired region to be processed on the base material efficiently for a short period of time when performing high-temperature heat treatment to the region near the surface of the base material uniformly for an extremely short period of time, or when performing low-temperature plasma processing to the base material by irradiating the base material with plasma by reactive gas or with plasma and the reactive gas flow at the same time.

### BRIEF DESCRIPTION OF THE DRAWINGS

FIGS. 1A and 1B are cross-sectional views showing a structure of a plasma processing apparatus according to Embodiment 1 of the present invention;

FIG. 2 a perspective view showing the structure of the plasma processing apparatus according to Embodiment 1 of the present invention;

FIGS. 3A and 3B are cross-sectional views showing a structure of a plasma processing apparatus according to Embodiment 2 of the present invention;

FIG. 4 a perspective view showing the structure of the plasma processing apparatus according to Embodiment 2 of the present invention;

FIG. 5 is a cross-sectional view showing a structure of a plasma processing apparatus according to Embodiment 3 of the present invention;

FIGS. 6A and 6B are cross-sectional views showing a structure of a plasma processing apparatus according to Embodiment 4 of the present invention;

FIG. 7 a perspective view showing the structure of the plasma processing apparatus according to Embodiment 4 of the present invention;

FIG. 8 is a cross-sectional view showing a structure of a plasma processing apparatus according to Embodiment 5 of the present invention;

FIGS. 9A and 9B are cross-sectional views showing a structure of a plasma processing apparatus according to Embodiment 6 of the present invention;

FIG. 10 is a cross-sectional view showing a structure of the plasma processing apparatus according to Embodiment 6 of the present invention;

FIG. 11 is a cross-sectional view showing a structure of a plasma processing apparatus according to Embodiment 7 of the present invention;

FIG. 12 is a cross-sectional view showing a structure of a plasma processing apparatus according to a related-art example; and

FIG. 13 is a conceptual view showing the relation between the depth from the outermost surface and the temperature according to the related-art example.

### DESCRIPTION OF EMBODIMENTS

Hereinafter, a plasma processing apparatus according to embodiments will be explained with reference to the drawings.

### Embodiment 1

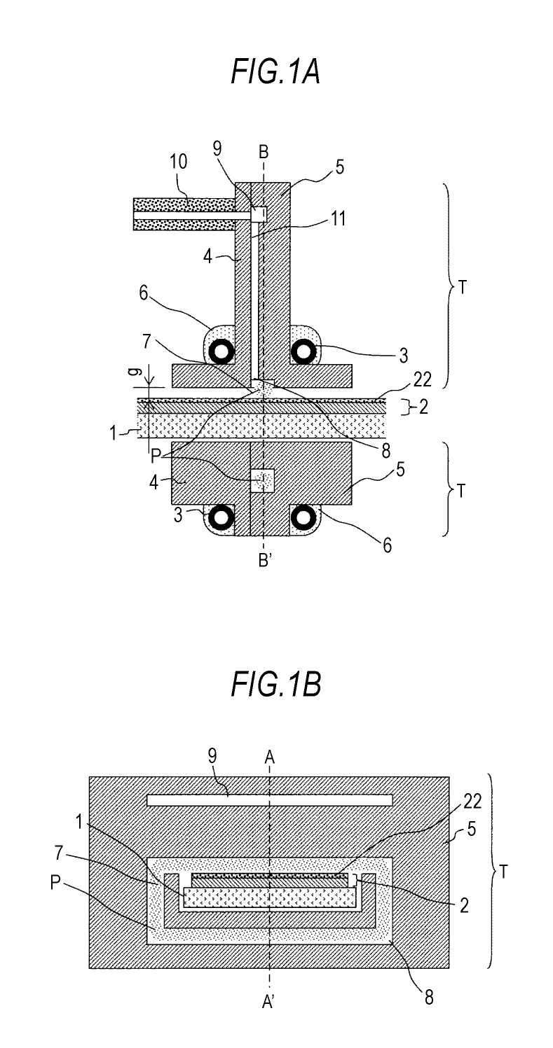

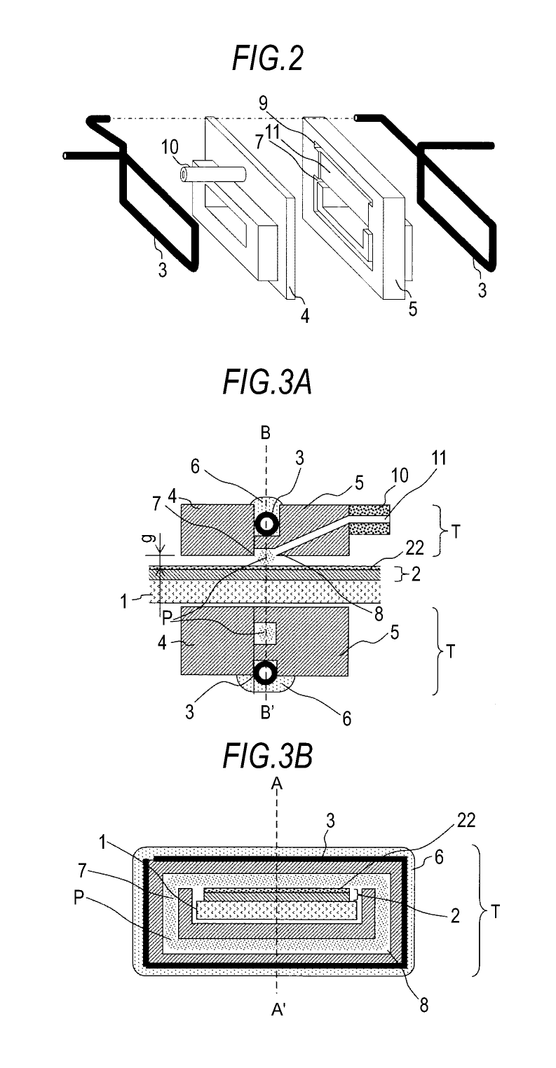

Hereinafter, Embodiment 1 of the present invention will be explained with reference to FIGS. 1A, 1B and FIG. 2.

FIG. 1A shows a structure of a plasma processing apparatus according to Embodiment 1 of the invention, which is a cross-sectional view of an inductive coupling type plasma torch unit cut along a surface perpendicular to a longitudinal direction. FIG. 1B is a cross-sectional view of the inductive coupling type plasma torch unit cut along a surface parallel to the longitudinal direction as well as perpendicular to a base material. FIG. 1A is a cross-sectional view cut along a dashed line A-A′ of FIG. 1B. FIG. 1B is a cross-sectional view cut along a dashed line B-B′ of FIG. 1A, and FIG. 2 is an assembly structure view of the inductive coupling type plasma torch unit shown in FIGS. 1A and 1B, in which perspective views of respective components (part of them) are aligned.

In FIGS. 1A, 1B and FIG. 2, a base material 2 is placed on a base material holding mechanism 1. An inductive coupling type plasma torch unit T is arranged so as to surround the outer periphery of the base material holding mechanism 1. In the inductive coupling type plasma torch unit T, a solenoid coil 3 made of an electric conductor is arranged in the vicinity of a first quartz block 4 and a second quartz block 5. A long chamber 7 made of a dielectric is demarcated by a space (internal space of the long chamber 7) surrounded by the first quartz block 4 and the second quartz block 5.

An inner wall surface on the closer side of the solenoid coil 3 of the long chamber 7 is a curved surface which is parallel to the solenoid coil 3. As the distance from the solenoid coil 3 to the long chamber 7 is equal at arbitrary positions of the solenoid coil 3 in this structure, inductive coupling type plasma can be generated with a small amount of high-frequency power, which realizes efficient plasma generation.

The inductive coupling type plasma torch unit T is surrounded by a shielding member (not shown) made of an electric conductor in which the whole member is grounded, which prevents leakage of high-frequency waves (noise) as well as prevents undesirable abnormal discharge efficiently.

The internal space of the long chamber 7 is surrounded by an annular groove provided in the second quartz block 5 and the first quartz block 4. That is, the entire long chamber 7 is configured to be surrounded by the dielectric. The internal space of the long chamber 7 has an annular shape. The annular shape mentioned here means a continuous closed shape having a string shape, which is not limited to a circular shape. In the embodiment, the long chamber 7 having a race-track shape (a continuous closed string shape formed by connecting straight-line portions as two long edges are connected to straight lines as two short edges on both ends) is cited as an example. Plasma P generated in the space inside the chamber 7 is jetted toward the base material 2 from a plasma jetting port as a slit-shaped opening 8 in the long chamber 7. The long chamber 7 is arranged so that the longitudinal direction thereof is parallel to the longitudinal direction of the plasma jetting port (opening 8).

The second quartz block 5 is provided with a plasma gas manifold 9. A gas supplied from a plasma gas supply pipe 10 to the plasma gas manifold 9 is introduced to the space inside the long chamber 7 through a plasma gas supply hole 11 (piercing hole) as a gas introducing portion provided in the second quartz block 5. According to the structure, the gas flow which is uniform in the longitudinal direction can be easily realized. The gas flow amount to be introduced into the plasma gas supply pipe 10 is controlled by providing a flow-amount control device such as a mass flow controller on the upstream thereof.

The plasma gas supply hole 11 is formed by providing a long slit-shaped hole in the longitudinal direction, however, it can be formed by providing plural circular holes in the longitudinal direction.

It is also preferable that a shielding-gas nozzle as a shielding-gas supply port at a portion close to the base material holding mechanism 1 though not shown. It is possible to reduce the mixture of a gas which is not necessary for processing or having an adverse effect on processing such as oxygen and carbon dioxide in the atmosphere onto a plasma irradiation surface by supplying a shielding gas in addition to the plasma gas suitable for generating the plasma. The shielding-gas supply port may be a slit having a long shape in parallel to the longitudinal direction of the plasma jetting port (opening 8), or may be many holes aligned in parallel to the longitudinal direction of the plasma jetting port (opening 8).

The solenoid coil 3 is made of a hollow copper pipe, in which the inside thereof is a coolant flow path. That is, cooling can be performed by allowing a coolant such as water to flow. It is also preferable that the coolant flow paths are provided in the first quartz block 4 and the second quartz block 5 in parallel to the longitudinal direction of the plasma jetting port (opening 8). The first quartz block 4 and the second quartz block 5 are adhered to the solenoid coil 3 by an adhesive 6 to thereby cool the first quartz block 4 and the second quartz block 5 through the adhesive 6.

The rectangular slit-shaped plasma jetting port (opening 8) is provided and the base material holding mechanism 1 (or the base material 2 on the base material holding mechanism 1) is arranged so as to face the plasma jetting port (opening 8). When high-frequency power is supplied from a not-shown high frequency power supply to the solenoid coil 3 while supplying the gas into the long chamber 7 and jetting the gas from the plasma jetting port (opening 8) toward the base material 2 in the above state, plasma processing can be performed to a thin film 22 on the base material 2 by generating the plasma P in the space inside the long chamber 7 and irradiating the base material 2 with plasma jetted from the plasma jetting port (opening 8). The base material 2 is processed by moving the long chamber 7 and the base material holding mechanism 1 relatively in a direction perpendicular to the longitudinal direction of the plasma jetting port (opening 8). That is, the inductive coupling type plasma torch unit T or the base material holding mechanism 1 is moved in the right and left direction in FIG. 1A, namely, in the direction perpendicular to the sheet in FIG. 1B.

Various types of gases can be used as the gas to be supplied to the long chamber 7, but it is preferable to mainly use an inert gas when considering stability and ignitability of plasma and lifetime of members exposed to the plasma. Among them, Ar gas is typically used. When the plasma is generated only by using Ar, the plasma will be substantially high temperature (10,000K or more).

As the length of the plasma jetting port (opening 8) in the longitudinal direction is longer than the width of the base material 2 in this structure, the overall thin film 22 in the region near the surface of the base material 2 can be processed by performing scanning (the inductive coupling type plasma torch unit T and the base material holding mechanism 1 are relatively moved) once.

In the above plasma processing apparatus, the high-frequency power of 13.56 MHz is supplied from the high frequency power supply (not shown) to the solenoid coil 3 while supplying Ar gas or Ar+H₂ gas from the plasma jetting port (opening 8) into the long chamber 7 and jetting the gas from the plasma jetting port (opening 8) toward the base material 2. Thus, the plasma P is generated by generating a high-frequency electromagnetic field in the space inside the long chamber 7, thereby irradiating the base material 2 with the plasma from the plasma jetting port (opening 8). Additionally, heat treatment such as crystallization of the semiconductor film can be performed by scanning the plasma P.

As conditions of generating plasma, the following values are suitable, that is, the distance between the plasma jetting port (opening 8) and the base material 2 is 0.1 to 5 mm, the scanning speed is 50 to 3000 mm/s, the total flow amount of plasma gas is 1 to 100SLM, H₂ density in Ar+H₂ gas is 0 to 10%, the flow amount of shielding gas (N₂) is 1 to 100SLM and high-frequency power is approximately 0.5 to 10 kW. In the above amounts, values per a length 100 mm of the plasma jetting port (opening 8) are shown in the gas flow amount and the power. It may be preferable to input the amounts which are in proportion to the length of the plasma jetting port (opening 8) as parameters such as the gas flow amount and the power.

As described above, the long chamber 7 and the base material holding mechanism 1 are relatively moved in the direction perpendicular to the longitudinal direction of the plasma jetting port (opening 8) while the longitudinal direction of the plasma jetting port (opening 8) and the base material holding mechanism 1 are arranged in parallel. As a result, it is possible to configure the device so that the length of the plasma to be generated and the length of the base material 2 to be processed are approximately equivalent.

Though the details of the structure inside the plasma torch is not disclosed in Patent Document 6 shown in the related-art examples, it is presumable that the inside of the plasma torch is a block of space having a rectangular parallelepiped shape in the same manner as a common cylindrical inductive coupling type plasma torch unit. When the atmospheric inductive coupling type plasma is generated in such space, a toric (donut-shaped) plasma is easily generated in the chamber. That is, the toric-shaped plasma is generated inside the chamber having the rectangular parallelepiped shape, therefore, only part of plasma in the chamber becomes extremely high density plasma, which makes difficult to perform uniform processing in the longitudinal direction.

Moreover, in Non-Patent Document 2 shown in the related-art examples, it is disclosed that the high-temperature plasma can be stably maintained by shutting the high-temperature plasma in the long chamber having the race-track shape. In the long plasma torch having the above structure, the plasma torch unit including the race track is positioned on the outer periphery of the base material and the base material holding mechanism.

As has been discussed in the same example, the donut-shape will shrink on the nature of the annular plasma, therefore, the high-temperature plasma is approached in a direction apart from the base material in the chamber.

Accordingly, it is difficult to obtain sufficient thermal efficiency. Whereas in the embodiment, as the long annular chamber is formed, the extended long plasma P having the race track shape is generated along the shape thereof. Furthermore, as the annular chamber is arranged on the outer periphery of the base material, the high-temperature plasma is approached in a direction coming close to the base material. Therefore, it is possible to perform processing which is uniform in the longitudinal direction with remarkably higher thermal efficiency.

### Embodiment 2

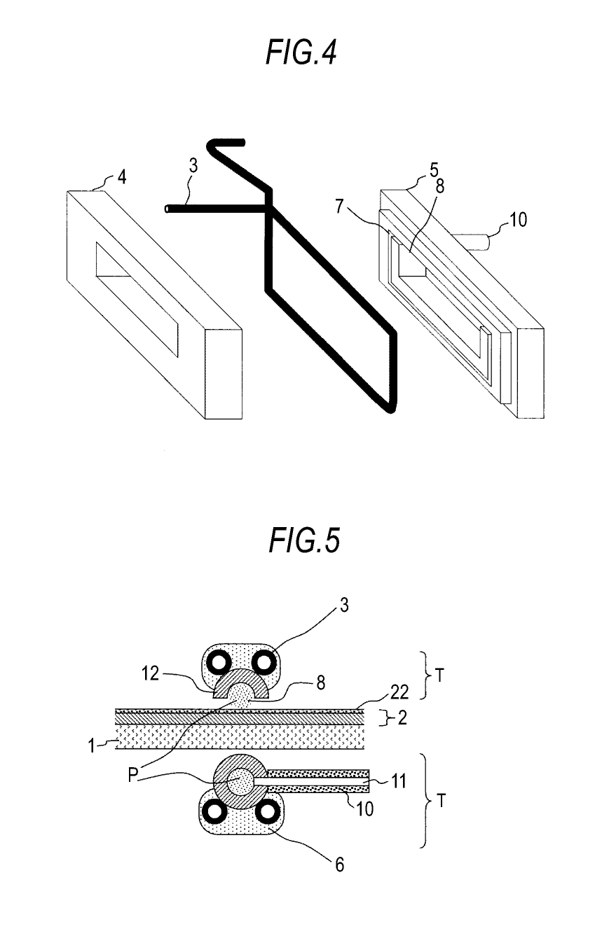

Hereinafter, Embodiment 2 of the invention will be explained with reference to FIGS. 3A, 3B and FIG. 4.

FIG. 3A shows a structure of a plasma processing apparatus according to Embodiment 2 of the invention and is a cross-sectional view of an inductive coupling type plasma torch unit cut along a surface perpendicular to a longitudinal direction, which corresponds to FIG. 1A. FIG. 3B is a cross-sectional view of the inductive coupling type plasma torch unit cut along a surface parallel to the longitudinal direction as well as perpendicular to a base material.

FIG. 3A is a cross-sectional view cut along a dashed line A-A′ of FIG. 3B. FIG. 3B is a cross-sectional view cut along a dashed line B-B′ of FIG. 3A and FIG. 4 is an assembly structure view of the inductive coupling type plasma torch unit shown in FIGS. 3A and 3B, in which perspective views of respective components (part of them) are aligned. In Embodiment 2 and other embodiments, the same components as Embodiment 1 are denoted by the same symbols and the explanation thereof will be omitted.

Embodiment 2 differs from Embodiment 1 in a point that the plasma gas supply pipe 10 is not connected to a side surface of the first quartz block 4 or the second quartz block 5 in a direction parallel to the base material but connected to a side surface of the long chamber 7 in a direction perpendicular to the longitudinal direction of the long chamber 7, and the plasma gas supply hole 11 through which the gas is introduced from the plasma gas supply pipe 10 to the long chamber 7 is provided. Accordingly, it is possible to form a structure not having a convex portion on the surface perpendicular to the moving direction of the base material in the first quartz block 4 and the second quartz block 5.

In the above structure, the solenoid coil 3 can be arbitrarily arranged on the outer periphery of the first quartz block 4 and the second quartz block 5, particularly arranged on a plane perpendicular to the base material holding mechanism as well as the same plane as the long chamber 7. Therefore, the solenoid coil 3 and the long chamber 7 can be arranged at the equal distance as well as at the closest position, as a result, the inductive coupling type plasma can be generated with a small amount of high-frequency power, and efficient plasma generation can be realized.

It is also preferable that a concave portion is arranged in a region closest to the long chamber 7 on the surface perpendicular to the moving direction of the base material. The solenoid coil 3 can be arranged at a closer position to the long chamber 7, and plasma can be generated more efficiently.

### Embodiment 3

Hereinafter, Embodiment 3 of the invention will be explained with reference to FIG. 5.

FIG. 5 shows a structure of a plasma processing apparatus according to Embodiment 3 of the invention and is a cross-sectional view of an inductive coupling type plasma torch unit T cut along a surface perpendicular to a longitudinal direction, which corresponds to FIG. 1A. Embodiment 3 differs from Embodiment 1 and Embodiment 2 in a point that the long chamber 7 is not formed by providing the space in the quartz blocks but an annular long chamber is formed by connecting a hollow first quartz tube 12 in a ring shape.

An opening is provided as the plasma jetting port (opening 8) at a region of part of the above hollow quartz tube, which faces the base material. It is also possible to supply the gas to the quartz tube by connecting the plasma gas supply pipe 10 to the long chamber 7.

In the above structure, the solenoid coil 3 and the long chamber 7 can be arranged at the equal distance as well as at the closest position in arbitrary positions of the solenoid coil 3, as a result, the inductive coupling type plasma can be generated with a small amount of high-frequency power, and efficient plasma generation can be realized. Moreover, there are advantages that the long chamber 7 can be easily formed as well as the inductive coupling type plasma torch unit T can be simply formed as the device can be formed by connecting the quartz tube.

### Embodiment 4

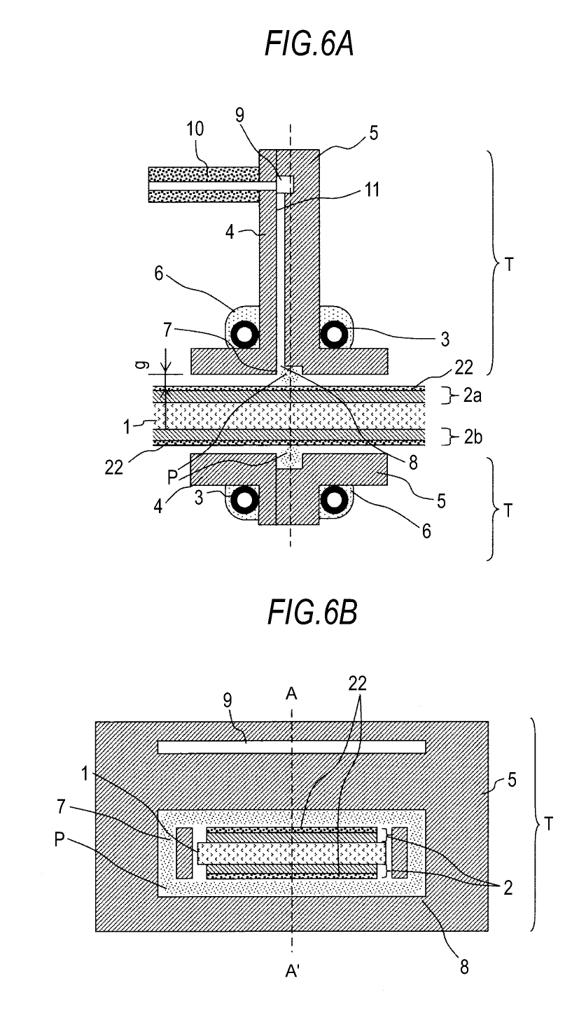

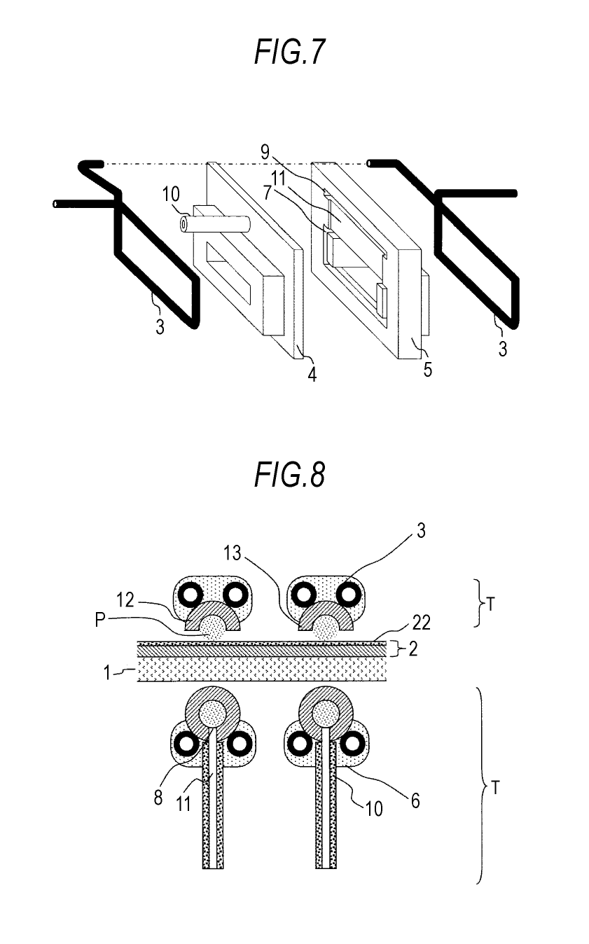

Hereinafter, Embodiment 4 of the invention will be explained with reference to FIGS. 6A and 6B.

FIG. 6A shows a structure of a plasma processing apparatus according to Embodiment 4 of the invention and is a cross-sectional view of an inductive coupling type plasma torch unit cut along a surface perpendicular to a longitudinal direction, which corresponds to FIG. 1A. FIG. 6B is a cross-sectional view of the inductive coupling type plasma torch unit T cut along a surface parallel to the longitudinal direction as well as perpendicular to a base material. FIG. 6A is a cross-sectional view cut along a dashed line A-A′ of FIG. 6B.

Embodiments 1, 2 and 3 have a structure of single-sided processing in which plasma processing is performed in a state where a base material 2a is placed only on an upper surface side of the base material holding mechanism 1. On the other hand, in Embodiment 4, a base material 2b is also fixed on a lower surface side of the base material holding mechanism 1 by a well-known holding method such as vacuum adsorption, electrostatic adsorption or clamping, thereby performing plasma processing to the base material on the surface side and the base material on the back side of the base material holding mechanism at the same time in a series of process.

According to the above structure, the throughput of processing the base material doubles, which is an advantage that process costs can be further reduced. Additionally, the base material holding mechanism can be designed, for holding the base material, to be provided in front and rear of the inductive coupling type plasma torch unit T in the moving direction, in other words, in the right and left direction on the sheet in FIG. 6A and/or right and left of the inductive coupling type plasma torch unit T in the moving direction, in other words, in the front and back direction on the sheet of FIG. 6A, thereby performing plasma processing to the surface side and the back side of the base material at the same time. According to the structure, plasma processing for obtaining contrastive temperature profiles in the surface and the back can be performed.

### Embodiment 5

Hereinafter, Embodiment 5 of the invention will be explained with reference to FIG. 8.

FIG. 8 shows a structure of a plasma processing apparatus according to Embodiment 5 of the invention and is a cross-sectional view of an inductive coupling type plasma torch unit cut along a surface perpendicular to a longitudinal direction, which corresponds to FIG. 1A.

In Embodiment 5, a second quartz tube 13 is arranged in parallel to a surface forming a ring shape of the first quartz tube 12.

In the above structure, different types of gases can be arbitrarily controlled with respect to two gas supply systems. Various types of gases such as an etching gas, a doping gas and a deposition gas are supplied as additional gases according to the above structure, which allows various reactions to occur on the surface of the base material.

For example, when the device is used for patterning of a silicon nitride film, a nitride film is deposited 50 nm on a semiconductor film by a CVD method and a resist is patterned by a printing method and so on. 10SLM of Ar, 0.1SLM of CF4 and 0.05SLM of O2 are introduced into the first quartz tube 12 and 10 Kw of high-frequency power is applied to thereby generate plasma. At the same time, 10SLM of Ar and 0.1SLM of vaporized H2O are introduced into the second quartz tube 13 and 10 Kw of high-frequency power is applied to thereby generate plasma. When the plasma processing is performed to the above-described substrate with the nitride film to which resist has been patterned, the nitride film is etched by the plasma generated in the first quartz tube 12 and the resist is asked by the plasma generated in the second quartz tube 13, thereby patterning the nitride film on silicon.

For example, when boron is doped into the silicon substrate, 10SLM of Ar and 0.1SLM of BF3 are introduced into the first quartz tube 12 and 10 Kw of high-frequency power is applied to thereby generate plasma. At the same time, 10SLM of Ar is introduced into the second quartz tube 13 and 10 Kw of high-frequency power is applied to thereby generate high-temperature thermal plasma. When the plasma processing is performed to the silicon substrate, boron is doped by the plasma generated in the first quartz tube 12, and the doped boron is activated and diffused by performing heat treatment in the second quartz tube 13. Moreover, for example, 10SLM of Ar, 0.1SLM of vaporized TEOS and 0.05SLM of O2 are introduced into the first quartz tube 12 and 1 Kw of high-frequency power is applied to thereby generate plasma.

Also, 10SLM of Ar is introduced into the second quartz tube 13 and 8 Kw of high-frequency power is applied to thereby generate high-temperature thermal plasma. When the plasma processing is performed to the silicon substrate, an oxide film can be formed on the surface of the silicon substrate. The same advantages can be obtained also by introducing a silane-series gas and oxygen into the first quartz tube 12, in addition to TEOS, and when B2H6 is introduced at the same time, BSG can be obtained as well as when PH3 is introduced, PSG can be obtained.

There is also an advantage that thermal profiles can be arbitrarily set by arranging the first quartz tube 12 and the second quartz tube 13 at arbitrary positions. For example, a gap between the first quartz tube 12 and the base material is set to 0.2 mm, a gap between the second quartz tube 13 is set to 2 mm and the long slit is directed to the travelling direction of the base material. A distance between the first quartz tube 12 and the second quartz tube 13 is set to 10 mm, and the moving speed of the torch unit is set to 100 cm/second. According to the structure, the base material can be rapidly heated by the second quartz tube 12 and can be gradually cooled by the second quartz tube 13.

Additionally, a gap between the first quartz tube 12 and the base material is set to 2 mm and the long slit is directed to the opposite direction to the travelling direction of the base material. A gap between the second quartz tube 13 and the base material is set to 0.2 mm. A distance between the first quartz tube 12 and the second quartz tube 13 is set to 1 mm and the moving speed of the torch unit is set to 100 cm/second. According to the structure, thermal profiles in which the base material is gradually heated by the first quartz tube 12 as well as the base material is rapidly heated and rapidly cooled by the second quartz tube 13.

Though the structure in which the first quartz tube and the second quartz tube are arranged has been shown in Embodiment 5, it is also possible to perform multistage plasma processing by further increasing the number of annular chambers. Moreover, various types of reactive plasmas can be obtained by using various types of plasma gases, and it is naturally possible to perform various types of plasma processing by combining these processing.

### Embodiment 6

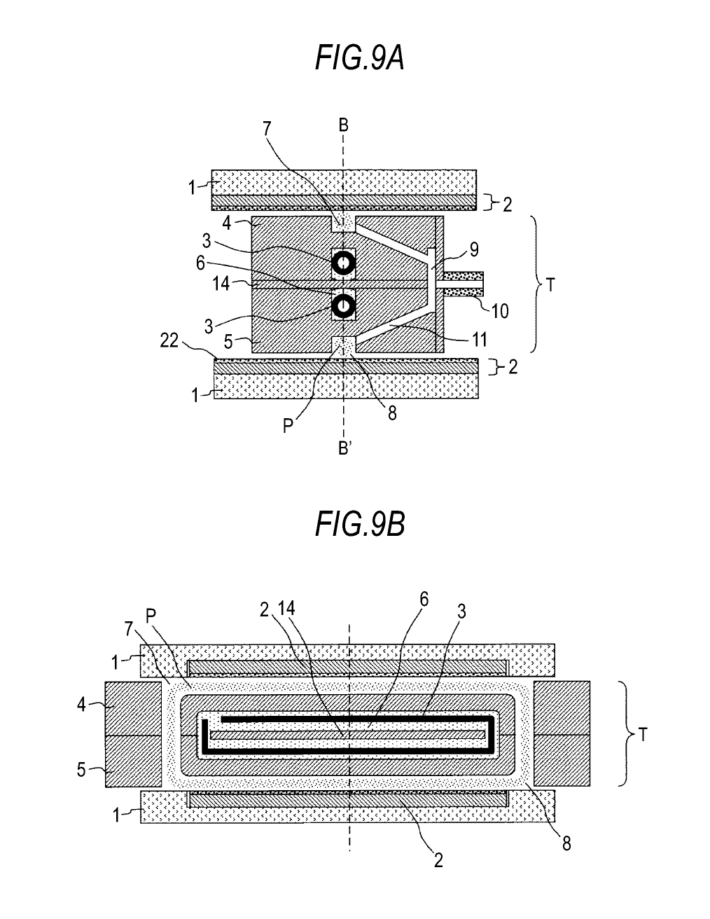

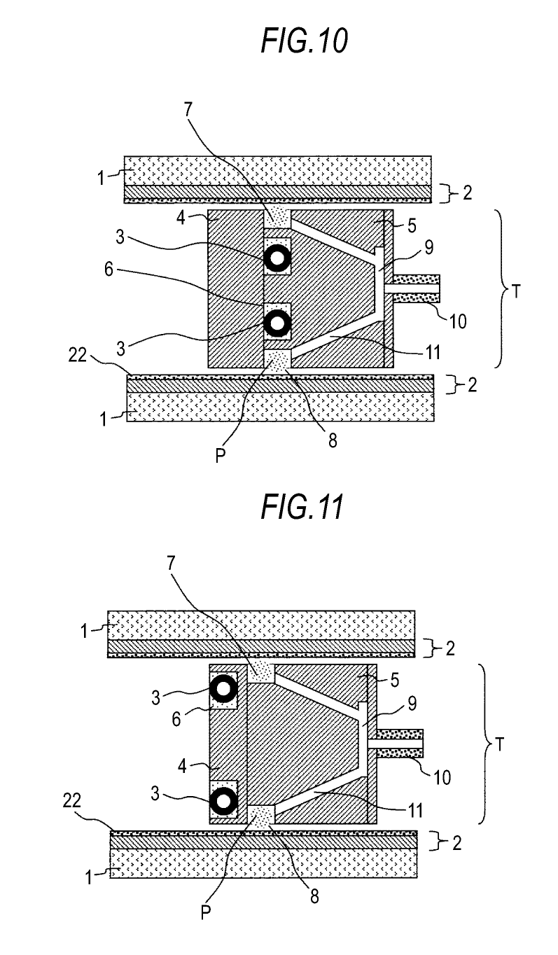

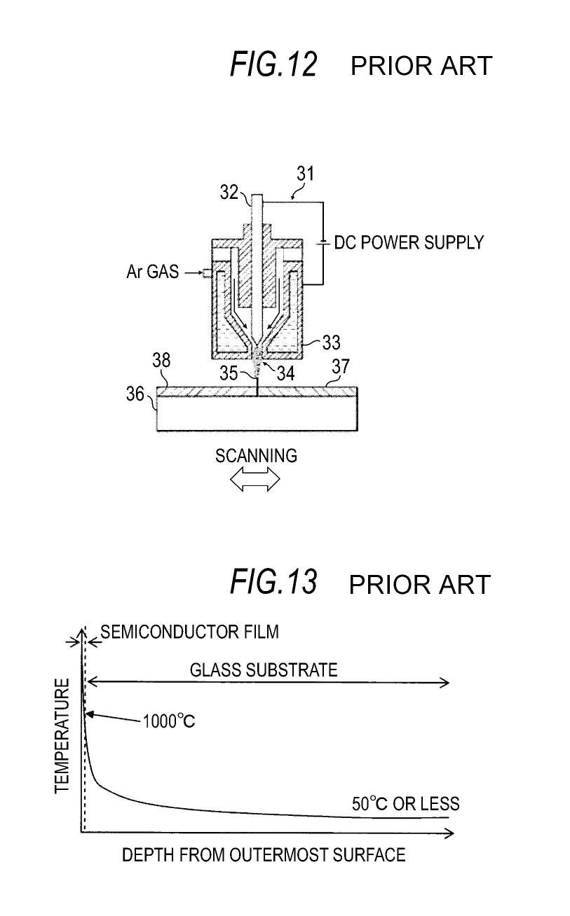

Hereinafter, Embodiment 6 of the invention will be explained with reference to FIGS. 9A, 9B and FIG. 10.

FIG. 9A shows a structure of a plasma processing apparatus according to Embodiment 6 of the invention and is a cross-sectional view of an inductive coupling type plasma torch unit cut along a surface perpendicular to a longitudinal direction, which corresponds to FIG. 1A. FIG. 9B is a cross-sectional view of the inductive coupling type plasma torch unit T cut along a surface parallel to the longitudinal direction, which corresponds to FIG. 1B.

Embodiment 6 has a structure in which the long chamber 7 is provided on the outside of the solenoid coil 3 so as to surround the solenoid coil 3 and upper and lower two base materials 2 are arranged outside the long chamber 7. An insulating plate 14 is inserted inside the solenoid coil 3 for preventing abnormal discharge between the upper side and the lower side of the solenoid coil 3.

According to the structure, plural base materials 2 can be processed at the same time.

Though two base materials 2 can be processed at the same time by forming the long chamber 7 and the solenoid coil 3 to have the long shape in Embodiment 6, it is also preferable that the long chamber 7 and the solenoid coil 3 are formed to have an arbitrary polygonal shape (n-sided polygon) to thereby process n-pieces of base materials 2 at the same time.

Furthermore, the first quartz block 4 and the second quartz block 5 are formed by two dielectric blocks respectively facing two base materials 2, however, it is also preferable that the first quartz block 4 and the second quartz block 5 are formed by two dielectric blocks separated in a direction in which the base materials 2 relatively move with respect to the long chamber 7 in a direction perpendicular to the longitudinal direction of the opening 8 as shown in FIG. 10.

### Embodiment 7

Hereinafter, Embodiment 7 of the invention will be explained with reference to FIG. 11.

FIG. 11 shows a structure of a plasma processing apparatus according to Embodiment 7 of the invention and is a cross-sectional view of an inductive coupling type plasma torch unit cut along a surface perpendicular to a longitudinal direction, which corresponds to FIG. 1A.

In Embodiment 7, the long chamber 7 is provided in parallel to the solenoid coil 3, and upper and lower two base materials 2 are arranged outside the long chamber 7. Moreover, the first quartz block 4 and the second quartz block 5 are formed by two dielectric blocks separated in a direction in which the base materials 2 relatively move with respect to the long chamber 7 in a direction perpendicular to the longitudinal direction of the opening 8.

Also according to the above structure, plural base materials 2 can be processed at the same time.

The plasma processing apparatus and the method thereof described above are merely typical examples in the application range of the present invention.

For example, the inductive coupling type plasma torch unit T may scan the fixed base material holding mechanism 1, and it is also preferable that the base material holding mechanism 1 can scan the fixed inductive coupling type plasma torch unit T. Also, a material forming the annular chamber may be quartz, or various dielectrics such as silicon nitride and aluminum oxide. The annular chamber may be formed by using bonded blocks with grooves or tubes having various shapes, or by using other methods.

The various structures of the invention enable high-temperature processing of the region near the surface of the base material 2. Accordingly, the present invention can be applied to not only the crystallization of the semiconductor film for the TFT and quality improvement of the semiconductor film for the solar cell explained in detail in the related-art examples but also various surface processing such as the cleaning or the reduction of degassing in a protective layer of a plasma display panel, surface planarization or the reduction of degassing in a dielectric layer made of the aggregation of silica microparticles, reflow soldering of various electronic devices and plasma doping using a solid impurity source. As a method of manufacturing solar cells, the present invention can be also applied to a method in which powder obtained by breaking up a silicon ingot is applied on the base material and irradiated with plasma to fuse the silicon to thereby obtain a polycrystalline silicon film.

In order to facilitate the ignition of plasma, it is possible to use an ignition source. As the ignition source, a sparking devise for ignition used to a gas-powered water heater and the like can be used.

In the above description, the word “thermal plasma” has been used for simplification, it is strictly difficult to discriminate between the thermal plasma and the low-temperature plasma, and it is also difficult to sort types of plasmas only based on the thermal equilibrium as commented in Yasunori Tanaka, “nonequilibrium property in thermal plasma” journal of plasma and fusion research, Vol. 82, no. 8 (2006) pp. 479-483, the contents of which are incorporated herein by reference. An object of the present invention is to perform heat treatment to the base material, and the present invention can be applied to techniques of emitting high-temperature plasma regardless of terms such as the thermal plasma, the thermal equilibrium plasma and the high-temperature plasma.

The case where the high-temperature heat treatment is uniformly performed to the region near the surface of the base material for an extremely short period of time has been explained in detail as an example, however, the present invention can be also applied to a case where low-temperature plasma processing is performed to the base material by irradiating the base material with the plasma by the reactive gas or with the plasma and the reactive gas flow at the same time. When the reactive gas is mixed into the plasma gas, the base material is irradiated with the plasma by the reactive gas to thereby realize etching or CVD.

It is also possible to realize plasma processing such as etching, CVD and doping by irradiating the base material with the plasma and the reactive gas flow at the same time by supplying a gas including a reactive gas as a shielding gas while using a noble gas or a gas formed by adding a small amount of an H₂ gas to the noble gas as a plasma gas. When a gas mainly containing argon is used as the plasma gas, thermal plasma is generated as explained in detail in Embodiments.

On the other hand, when a gas mainly containing helium as the plasma gas is used, relatively low-temperature plasma can be generated. It is possible to perform processing such as etching and deposition without heating the base material excessively. As reactive gases used for etching, halogen containing gas such as CₓF_{y} (x, y are natural numbers) and SF₆ can be used, thereby etching silicon, silicon compounds and so on. When O₂ is used as the reactive gas, it is possible to remove organic matters or to perform resist asking. As reactive gases used for CVD, monosilane, disilane and so on can be cited, which allows the deposition of silicon or silicon compounds.

It is also possible to deposit a silicon oxide film by using a mixed gas of an organic gas containing silicon represented by TEOS (Tetraethoxysilane) and O₂. Additionally, various types of low-temperature plasma processing such as surface processing for improving the quality of water repellency and hydrophilicity. As the present invention applies the inductive coupling type unit, transition to the arc discharge hardly occurs even when high power density per a unit volume is inputted as compared with related-art examples (for example, the example disclosed in Patent Document 7), therefore, plasma with higher density can be generated, as a result, high reaction speed can be obtained and the entire desired region to be processed on the base material can be efficiently processed for a short period of time.

As described above, the present invention can be applied to crystallization of a semiconductor film for the TFT and quality improvement of the semiconductor film for the solar cell. Naturally, the present invention is effective on the processing of the entire desired region to be processed on the base material efficiently for a short period of time by generating plasma stably and efficiently when performing high-temperature heat treatment uniformly to a region near the surface of the base material for an extremely short period of time in various surface processing such as the cleaning or the reduction of degassing in the protective layer of the plasma display panel, surface planarization or the reduction of degassing in the dielectric layer made of the aggregation of silica microparticles, reflow soldering of various electronic devices and plasma doping using the solid impurity source. The present invention is also effective on the processing of the entire desired region to be processed on the base material efficiently for a short period of time in the low-temperature plasma processing such as etching, deposition, doping and surface quality improvement in manufacture of various electronic devices.

What is claimed is:

1. A plasma processing apparatus comprising:
an annular chamber surrounded by a dielectric member;
an opening communicating to the annular chamber;
a gas supply pipe for introducing gas into the annular chamber;
a coil provided in the vicinity of the annular chamber; and
a high-frequency power supply connected to the coil,
wherein a base material holding mechanism holding a base material inside the annular chamber and the coil is further included.

2. A plasma processing apparatus comprising:
an annular chamber surrounded by a dielectric member;
an opening communicating to the annular chamber;
a gas supply pipe for introducing a gas into the annular chamber;
a coil provided in the vicinity of the annular chamber; and
a high-frequency power supply connected to the coil,
wherein a base material holding mechanism holding plural base materials outside the annular chamber is further included.

3. The plasma processing apparatus according to claim 1, further including a moving mechanism in which the annular chamber has a long shape, the opening is long and linear, the coil has a long shape in a direction parallel to the longitudinal direction of the opening, and the chamber and the base material holding mechanism can be relatively moved in a direction perpendicular to the longitudinal direction of the opening.

4. The plasma processing apparatus according to claim 3,
wherein a coolant flow path is provided inside the dielectric member in parallel to the longitudinal direction of the opening.

5. The plasma processing apparatus according to claim 3, further including a dielectric tube provided in parallel to a longitudinal direction of the opening, the dielectric tube having a coolant flow path inside and being bonded to the dielectric member.

6. The plasma processing apparatus according to claim 1,
wherein a path communicating the annular chamber to the opening is formed by a gap of 1 mm or less.

7. The plasma processing apparatus according to claim 1,
wherein a size of the annular chamber is 1 mm or more to 10 mm or less.

8. The plasma processing apparatus according to claim 1,
wherein an outside diameter of the annular chamber is 10 mm or more.

9. A plasma processing method comprising the steps of:
injecting gas from an opening communicating to an annular chamber toward a base material held inside the annular chamber while supplying the gas into the annular chamber surrounded by a dielectric member; and
supplying high-frequency power to a coil to generate a high-frequency electromagnetic field inside the annular chamber and generate plasma to thereby process the surface of the base material.

10. A plasma processing method comprising the steps of:
injecting gas from an opening communicating to an annular chamber toward plural base materials held outside the annular chamber while supplying the gas into the annular chamber surrounded by a dielectric member; and
supplying high-frequency power to a coil to generate a high-frequency electromagnetic field inside the annular chamber and generate plasma to thereby process the surface of the base material.

11. The plasma processing apparatus according to claim 2, further including a moving mechanism in which the annular chamber has a long shape, the opening is long and linear, the coil has a long shape in a direction parallel to the longitudinal direction of the opening, and the chamber and the base material holding mechanism can be relatively moved in a direction perpendicular to the longitudinal direction of the opening.

12. The plasma processing apparatus according to claim 11,
wherein a coolant flow path is provided inside the dielectric member in parallel to the longitudinal direction of the opening.

13. The plasma processing apparatus according to claim 11, further including a dielectric tube provided in parallel to a longitudinal direction of the opening, the dielectric tube having a coolant flow path inside and being bonded to the dielectric member.

14. The plasma processing apparatus according to claim 2, wherein a path communicating the annular chamber to the opening is formed by a gap of 1 mm or less.

15. The plasma processing apparatus according to claim 2, wherein a size of the annular chamber is 1 mm or more to 10 mm or less.

16. The plasma processing apparatus according to claim 2, wherein an outside diameter of the annular chamber is 10 mm or more.
